(19) United States
(12) Patent Application Publication
(10) Pub. No.: US 2013/0258598 A1
(43) Pub. Date: Oct. 3, 2013

(54) ELECTRIC APPARATUS

(71) Applicant: ABB OY, Helsinki (FI)

(72) Inventors: Dan Millner, Helsinki (FI); Juha Tuomola, Helsinki (FI); Juha Hamari, Helsinki (FI)

(73) Assignee: ABB Oy, Helsinki (FI)

(21) Appl. No.: 13/851,617

(22) Filed: Mar. 27, 2013

(30) Foreign Application Priority Data
Apr. 2, 2012 (EP) 12397512.0

(51) Int. Cl. H05K 5/02

(52) U.S. Cl. CPC H05K 5/0213
USPC 361/704

(57) ABSTRACT

The disclosure relates to an electric apparatus including an electric device which, during use, generates heat, and a housing enclosing the electric device from the surrounding environment. In order to avoid problems caused by water, the electric apparatus including a receptacle for containing a desiccant. The receptacle has an opening allowing gas to flow between an interior of the receptacle and an interior of the housing in order for the desiccant to come into contact with moisture in the housing, and the receptacle is thermally connected to the electric device for transferring heat from the electric device to the desiccant for removing moisture from the desiccant.

### RELATED APPLICATION(S)

This application claims priority under 35 U.S.C. §119 to European Patent Application No. 12397512.0 filed in Europe on Apr. 2, 2012, the entire contents of which is hereby incorporated by reference in its entirety.

1. Field

This disclosure relates to an electric apparatus, and for example, to avoiding damages caused to an electric apparatus by water.

2. Background Information

There is known an electric apparatus with an electric device arranged in a housing enclosing the electric apparatus from the surrounding environment. Even though the housing can efficiently enclose the electric apparatus by preventing water and air from entering the apparatus from the outside, water in the housing can still be a problem. During use of this known apparatus, heat generated by the electric device can be sufficient to prevent damages due to water. However, once the use of the electric apparatus ends and the temperature in the housing drops, moisture in the air inside the housing can, under certain conditions, condensate into water.

In a known apparatus an electric resistor is used for heating the inside of the housing when necessary. Such situations can occur when the use of the electric device has ended. Due to this heating, damages caused by water can be avoided.

However, a drawback can be the amount of energy needed for the electric resistor. This energy is more or less wasted, which is not acceptable due to the costs for obtaining the energy and due to environmental reasons.

### SUMMARY

An electric apparatus is disclosed, comprising: an electric device which, during use, generates heat; a housing enclosing the electric device from a surrounding environment for preventing dirt, air and water from entering the housing; and a receptacle containing a desiccant in the housing, the receptacle having an opening for allowing gas to flow between an interior of the receptacle and an interior of the housing in order for the desiccant to come into contact with moisture in the housing; wherein the receptacle is thermally connected to the electric device for transferring heat from the electric device to the desiccant for removing moisture from the desiccant.

### BRIEF DESCRIPTION OF THE DRAWINGS

In the following the present disclosure will be described in closer detail by way of example and with reference to the attached drawings, in which:

FIG. 1 is a block diagram of an electric apparatus according to an exemplary embodiment of the disclosure;

FIG. 2 illustrates a receptacle of the apparatus according to an exemplary embodiment of the disclosure in FIG. 1; and

FIG. 3 is an exploded view of the receptacle according to an exemplary embodiment of the disclosure in FIG. 2.

### DETAILED DESCRIPTION

Exemplary embodiments of the disclosure can provide an electric apparatus in which problems caused by water can be avoided simultaneously with minimizing waste of energy.

The use of a receptacle containing desiccant makes it possible to collect moisture from within the housing of the electric apparatus such that the risk of damages due to water can be minimized also when the electric device is out of use. A thermal connection between the receptacle and the electric device is utilized for removing moisture from the desiccant while the electric apparatus is in use. Therefore, excess heat produced by the electric device can be used for preparing the desiccant for a new period during which the desiccant collects moisture.

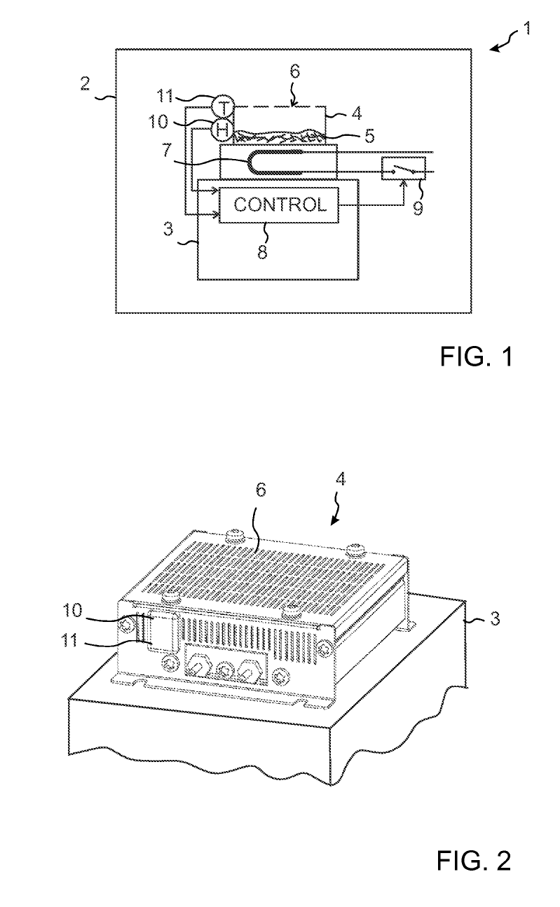

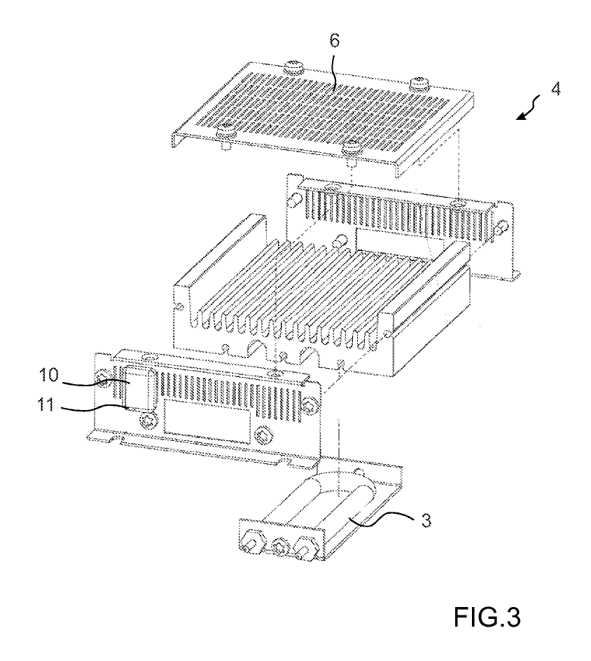

FIGS. 1 to 3 illustrate an electric apparatus 1 according to an exemplary embodiment of the disclosure. In the following explanations it can be, by way of example, assumed that the electric device is a periodically operating electric device, in other words an electric device which is not continuously in use but can be instead commonly out of use for relatively long periods of time. An example of such a periodically operating electric device is a PV inverter (Photovoltaic Inverter). For example, an inverter converting the variable DC output of a solar panel into an AC output. Such a PV inverter is for practical reasons out of use at night when sunlight is not available. However, it should be observed that the disclosure can be implemented also for other electric apparatuses.

The electric apparatus 1 includes a housing 2 which encloses an electric device 3 from the surrounding environment. In the case of a closed and tight housing for outdoor installation, the housing has been manufactured to efficiently prevent dirt and water from entering the housing 2. In most implementations such a closed and tight housing can be practically air-tight without a need for any ventilation arrangement to the surrounding environment. However, if necessary, the housing can be provided with an opening to the outside which can be covered with a layer of a material allowing moisture to pass through it. In this way once the interior of the housing is heated, moisture can pass to the surroundings of the housing through the opening and the material layer.

During use, the electric device 3 generates heat. The generated excess heat from the electric device 3 can be sufficient to raise the temperature inside the housing 2 sufficiently to avoid problems due to water. However, when the electric device 3 is not in use, the temperature inside the housing 2 falls and moisture in the air inside the housing 2 can under certain conditions condensate into water.

In an exemplary embodiment according to the disclosure, the electric apparatus 1 is provided with a receptacle 4 for containing a desiccant 5. In this connection the term “desiccant” refers to a material capable of obtaining water from the gas (usually air) surrounding it such that the surrounding gas can be kept dry and almost free of moisture. The receptacle 4 has an opening 6, or actually several openings in the illustrated example, which allows gas to flow between the interior of the receptacle 4 and the interior of the housing 2. In this way the desiccant 5 comes into contact with moisture in the housing 2, and the air inside the housing 2 can be kept sufficiently dry, also during periods when the electric device 3 is not in use.

One suitable desiccant 5 for use in the illustrated example is silica gel, which is an amorphous silicon dioxide usually available as small crystals. Silica gel has an excellent capability of absorbing moisture directly from air. Additionally, once the silica gel has absorbed as much water as it can, it can be regenerated such that the water or moisture is removed from the silica gel. Such regeneration is achieved by heating the silica gel to a sufficiently high temperature, usually to a temperature higher than 100° C., and by keeping the temperature at this level for a sufficient time period (usually a few hours). After such regeneration, the silica gel is again ready for absorbing water.

In the illustrated embodiment, the receptacle 4 is thermally connected to the electric device 3 for transferring heat from the electric device 2 to the desiccant 5 when the electric device 3 is in use. A thermal connection can be obtained, as in the illustrated example, by attaching the receptacle 4 to the electric device 2 such that heat can be conducted from the electric device to the receptacle 4. In that case the receptacle 4 can be attached or brought in direct contact with such a component of the electric device 3, which during use reaches a relatively high temperature. Such a component can be a cooling element of an IGBT module (Insulated Gate Bipolar Transistor) or an LCL filter, for example. Alternatively, the receptacle can be thermally connected to the electric device via a gas flow (such as air flow) transferring heat dissipated by the electric device to the receptacle. In that case the receptacle can be arranged into an air flow which exits a cooling element of the electric device, for example. Due to the thermal connection, excess heat generated by the electric device during use of the electric device can be utilized for removing moisture from the desiccant 5 in the receptacle 4.

In an exemplary embodiment of the disclosure the electric apparatus 1 includes an electric resistor 7 which is thermally connected to the receptacle 4 for heating the desiccant 5 such that moisture is removed from the desiccant 5. A controller 8, which can be implemented with electrical circuits only or as a combination of a computer program and electrical circuits, controls the electric resistor 7. In the illustrated example the controller 8 controls the electric resistor 7 via a switch 9 such that the electric supply to the electric resistor can be switched on and off depending on whether or not the electric resistor 7 needs to heat the receptacle 4 at that particular moment.

In addition to the controller 8, the electric apparatus 1 can, in some exemplary embodiments, be optionally provided with a sensor 10 for measuring the humidity in the housing 2 and/or with a sensor 11 for measuring the temperature in the housing 2. In the illustrated example both the sensor 10 for measuring the humidity and the sensor 11 for measuring the temperature provides the controller 8 with information about the temperature and humidity (amount of water in the air) in the housing.

In many implementations, the electric device 3 alone generates, during use, enough heat to raise the temperature inside the housing 2 sufficiently for removing moisture from the desiccant 5. However, if the controller 8 via the temperature sensor 11 detects that the temperature indicated by the sensor 11 is below a predetermined limit while the electric device is in use, the controller 8 controls the electric resistor 7 via the switch 9 to heat the receptacle 4 for a predetermined time period, for example. In this way moisture can be removed from the desiccant 5, and it can be ensured that the desiccant 5 is able to keep the interior of the housing 2 dry once the use of the electric device 3 ends.

The controller 8 also monitors the humidity inside the housing 2 by the sensor 10. In case the air humidity indicated by the sensor 10 is above a predetermined limit, the controller 8 controls the electric resistor 7 via the switch 9 to heat the receptacle 4 for a predetermined time period, for example. In this way the temperature inside the housing 2 can be sufficiently raised to ensure that water will not cause any problems, and additionally, moisture can be removed from the desiccant 5. Situations where the air humidity is above a predetermined limit can occur while the electric device 3 is out of use for a relatively long period of time, during which the amount of water absorbed by the desiccant 5 will reach the maximum level that the desiccant can absorb.

It is to be understood that the above description and the accompanying figures are only intended to illustrate the present disclosure. It will be obvious to a person skilled in the art that the disclosure can be varied and modified without departing from the scope of the disclosure.

Thus, it will be appreciated by those skilled in the art that the present invention can be embodied in other specific forms without departing from the spirit or essential characteristics thereof. The presently disclosed exemplary embodiments are therefore considered in all respects to be illustrative and not restricted. The scope of the invention is indicated by the appended claims rather than the foregoing description and all changes that come within the meaning and range and equivalence thereof are intended to be embraced therein.

What is claimed is:

1. An electric apparatus, comprising:
an electric device which, during use, generates heat;
a housing enclosing the electric device from a surrounding environment for preventing dirt, air and water from entering the housing; and
a receptacle containing a desiccant in the housing, the receptacle having an opening for allowing gas to flow between an interior of the receptacle and an interior of the housing in order for the desiccant to come into contact with moisture in the housing;
wherein the receptacle is thermally connected to the electric device for transferring heat from the electric device to the desiccant for removing moisture from the desiccant.

2. The electric apparatus according to claim 1, comprising:
a cooling element for the electric device;
wherein the receptacle is thermally connected to the electric device via the cooling element, to which the receptacle is attached for conducting heat to the desiccant.

3. The electric apparatus according to claim 1, comprising:
wherein the receptacle is configured to be thermally connected to the electric device via a gas flow for transferring heat dissipated by the electric device to the receptacle.

4. The electric apparatus according to claim 1, comprising:
an electric resistor thermally connected to the receptacle for heating the desiccant such that moisture is removed from the desiccant; and
a controller for controlling the electric resistor to heat the desiccant.

5. The electric apparatus according to claim 1, comprising:
a sensor for measuring the temperature in the housing;
an electric resistor thermally connected to the receptacle for heating the desiccant such that moisture is removed from the desiccant; and
a controller arranged to activate the electric resistor to heat the desiccant when the temperature indicated by the sensor is below a predetermined limit while the electric device is in use.

6. The electric apparatus according to claim 1, comprising:
a sensor for measuring air humidity in the housing;
an electric resistor thermally connected to the receptacle for heating the desiccant such that moisture is removed from the desiccant; and
a controller arranged to activate the electric resistor to heat the desiccant when the air humidity indicated by the sensor is above a predetermined limit.

7. The electric apparatus according to claim 1, wherein the electric device is a periodically operating electric device.

8. The electric apparatus according to claim 1, wherein the desiccant is silica gel.

9. The electric apparatus according to claim 1, wherein the housing is a closed and tight housing for outdoor installation of an electric device.

10. The electric apparatus according to claim 1, wherein the electric apparatus is an inverter converting a DC input from a solar panel to an AC output.
